(19) United States
(12) Patent Application Publication
(10) Pub. No.: US 2014/0266482 A1
(43) Pub. Date: Sep. 18, 2014

(54) NEGATIVE CAPACITANCE CIRCUIT, RESONANCE CIRCUIT AND OSCILLATOR CIRCUIT

(71) Applicant: NIHON DEMPA KOGYO CO., LTD., TOKYO (JP)

(72) Inventor: TAKEHITO ISHII, SAITAMA (JP)

(73) Assignee: NIHON DEMPA KOGYO CO., LTD., TOKYO (JP)

(21) Appl. No.: 14/203,563

(22) Filed: Mar. 11, 2014

(30) Foreign Application Priority Data
Mar. 12, 2013 (JP) 2013-049253
Mar. 12, 2013 (JP) 2013-049254
Feb. 17, 2014 (JP) 2014-027158
Feb. 17, 2014 (JP) 2014-027159

(51) Int. Cl. H03B 5/30; H03H 11/52

(52) U.S. Cl. CPC H03B 5/30; H03H 11/52
USPC 331/154; 333/216

(57) ABSTRACT

A resonance circuit includes a first resonator, a second resonator, a capacitance element and an inverting amplifier, and a negative capacitance circuit. The second resonator is connected to the first resonator in series. The capacitance element and the inverting amplifier are connected to one another in series. The capacitance element and the inverting amplifier are connected to the first resonator in parallel. The negative capacitance circuit is connected between a node and ground. The node is disposed between the first resonator and the second resonator.

### CROSS-REFERENCE TO RELATED APPLICATIONS

This application claims the priority benefit of Japan application serial Nos. 2013-049253 and 2013-049254, filed on Mar. 12, 2013 and Nos. 2014-027158 and 2014-027159, filed on Feb. 17, 2014. The entirety of each of the above-mentioned patent applications is hereby incorporated by reference herein and made a part of this specification.

### TECHNICAL FIELD

This disclosure relates to a negative capacitance circuit, a resonance circuit and an oscillator circuit.

### DESCRIPTION OF THE RELATED ART

An anti-resonance circuit is conventionally known, which can adjust an oscillation frequency in a frequency range wider than a frequency range adjustable by a single crystal resonator by using more than one crystal resonators whose resonance frequencies are different from each other (for example, see Japanese Unexamined Patent Application Publication No. 2007-295256 (hereinafter referred to as Patent Literature 1)).

FIG. 17 illustrates an exemplary configuration of a conventional anti-resonance circuit 400. In FIG. 17, the anti-resonance circuit 400 is connected to an output resistor 440 of an AC signal source 430 and a load resistor 450.

The anti-resonance circuit 400 includes a crystal resonator 411 and a crystal resonator 421 that are connected to different paths between the output resistor 440 and the load resistor 450. The crystal resonator 411 is connected to a first path in which an attenuator 412, an inductor 413, and a capacitor 414 are connected in series. The crystal resonator 411 is connected between the connecting point of the inductor 413 and capacitor 414, and ground. Similarly to the crystal resonator 411, the crystal resonator 421 is connected to a second path in which an attenuator 422, an inductor 423 and a capacitor 424 are connected in series. The crystal resonator 421 is connected between the connecting point of the inductor 423 and capacitor 424, and ground.

The crystal resonator 411 and the crystal resonator 421 respectively have different resonance frequencies, and are connected to each other via the capacitor 414 and capacitor 424. This causes the anti-resonance circuit 400 to resonate at a frequency between the resonance frequency of the crystal resonator 411 and the resonance frequency of the crystal resonator 421. The anti-resonance frequency of the anti-resonance circuit 400 varies by changing the attenuation rate of the attenuator 412 and attenuator 422.

Incidentally, the resonance frequency of a resonator having high Q such as a crystal resonator, and an Micro-Electro-Mechanical Systems (MEMS) resonator is expressed by f_{L}=(½π)√{(C₁+C_{L})/L₁C₁C_{L}}. Note that C₁ is a motional capacitance of an equivalent circuit in the resonator, and C_{L} is a load capacitance, and L₁ is a motional inductance of the resonator.

In an oscillator circuit using an MEMS resonator whose C₁ is relatively small, the adjustment of frequencies is performed by adjusting the bias voltage applied to a resonator. However, when a resonator whose C₁ is very small with respect to a capacitance value on the order of several pF that is achieved in an integrated circuit and an individual component is employed in the oscillator circuit, the resonance frequency can approximate f_{L}=(½π)√(1/L₁C₁) based on the relation of C_{L}>>C₁. Accordingly, the resonance frequency is determined based on L₁ and C₁ that the resonator has. Consequently, when the above-described resonator is used in the oscillator circuit, the temperature characteristic of the resonance frequency of the resonator is directly reflected to the temperature characteristic of the oscillation frequency.

Especially, the temperature characteristic of the resonance frequency of an MEMS resonator is around −30 ppm/° C., and a frequency variation range with respect to the temperature change is relatively large. Accordingly, in an oscillator circuit using the MEMS resonator, it is difficult to cancel the temperature change to obtain a stable oscillation frequency only by adjusting the bias voltage.

The anti-resonance circuit 400 illustrated in FIG. 17 can change an anti-resonance frequency in a frequency range wider than a case where the bias voltage of a single MEMS resonator is adjusted. In the anti-resonance circuit 400, however, the inductance values of the inductor 413 and inductor 423 should be sufficiently large in order to increase the value of Q at the anti-resonance frequency to the extent that the oscillator circuit can use. In particular, Patent Literature 1 discloses a value of 27 μH as an exemplary inductance value of the inductor 413 and inductor 423.

An inductor disadvantageously changes its inductance value significantly in response to temperature change. Also, it is difficult to adjust an inductance value in response to the variation of a resonator. Accordingly, a resonance circuit using an inductor cannot obtain an oscillation signal having a stable oscillation frequency. Furthermore, it is difficult to incorporate an inductor having an inductance value on the order of μH into an integrated circuit. Consequently, it is impossible to achieve the low cost mass production of oscillator circuits that can obtain an oscillation signal having a stable oscillation frequency using the conventional anti-resonance circuit 400.

On the other hand, as disclosed in Japanese Unexamined Patent Application Publication Nos. 2002-124713 and H08-204451, in the case where an negative capacitance circuit is configured by using an operational amplifier as an active element, the oscillation frequency of the oscillator circuit to which the negative capacitance circuit can be connected is disadvantageously limited to the extent of several MHz since the operation bandwidth of the operational amplifier is not sufficiently large.

Also, as disclosed in Japanese Unexamined Patent Application Publication No. S60-157317, International Publication Number WO 00/04647, and U.S. Pat. No. 7,609,111, in the case where a negative capacitance circuit is configured by combining a plurality of transistors, an undesired oscillation is unfortunately caused easily. In particular, in the case where a negative capacitance circuit is configured by using an emitter follower circuit, the Colpitts LC oscillator circuit is formed by a parasitic capacitor and a parasitic inductor near the emitter follower circuit, which sometimes causes an undesired oscillation at frequencies (such as GHz band) other than the resonance frequency of the connected resonator. In addition, a conventional negative capacitance circuit has a return gain S11 at high frequencies, so that when the negative capacitance circuit is connected to another circuit, an undesired oscillation is sometimes caused.

A need thus exists for a negative capacitance circuit, a resonance circuit, and an oscillator circuit which are not susceptible to the drawback mentioned above.

### SUMMARY

A resonance circuit according to the disclosure includes a first resonator, a second resonator, a capacitance element and an inverting amplifier, and a negative capacitance circuit. The second resonator is connected to the first resonator in series. The capacitance element and the inverting amplifier are connected to one another in series. The capacitance element and the inverting amplifier are connected to the first resonator in parallel. The negative capacitance circuit is connected between a node and ground. The node is disposed between the first resonator and the second resonator.

### BRIEF DESCRIPTION OF THE DRAWINGS

The foregoing and additional features and characteristics of this disclosure will become more apparent from the following detailed description considered with reference to the accompanying drawings, wherein:

FIG. 1 is a circuit diagram illustrating an exemplary configuration of an oscillator according to a first embodiment.

FIG. 2 is a circuit diagram illustrating a simulation circuit using an equivalent circuit of a resonance circuit according to the first embodiment.

FIG. 3A is a graph illustrating an exemplary frequency characteristic of a gain of the resonance circuit according to the first embodiment.

FIG. 3B is a graph illustrating an exemplary frequency characteristic of a phase of the resonance circuit according to the first embodiment.

FIG. 3C is a graph illustrating a frequency characteristic of a gain of the resonance circuit according to a comparative example.

FIG. 4 is a circuit diagram illustrating an exemplary configuration of a resonance circuit according to a second embodiment.

FIG. 5 is a circuit diagram illustrating an exemplary configuration of a resonance circuit according to a third embodiment.

FIG. 6A is a graph illustrating an exemplary frequency characteristic of a gain of the resonance circuit according to the third embodiment.

FIG. 6B is a graph illustrating an exemplary frequency characteristic of a phase of the resonance circuit according to the third embodiment.

FIG. 7 is a circuit diagram illustrating an exemplary configuration of an oscillator according to a fourth embodiment.

FIG. 8A is a circuit diagram illustrating an exemplary configuration of an oscillator circuit according to a fifth embodiment.

FIG. 8B illustrates an equivalent circuit of a negative capacitance circuit.

FIG. 9 is a graph illustrating an exemplary frequency characteristic of an equivalent RC parallel circuit when a negative capacitance circuit is observed from an external interface.

FIG. 10 is a graph illustrating an exemplary impedance characteristic of a resonator.

FIG. 11 is a graph illustrating an exemplary reflection characteristic when the negative capacitance circuit is observed from the external interface.

FIG. 12 is a circuit diagram illustrating an exemplary configuration of an oscillator circuit of a comparative example.

FIG. 13 is a graph illustrating an exemplary frequency characteristic of the equivalent RC parallel circuit when a negative capacitance circuit of the comparative example is observed from an external interface.

FIG. 14 is a graph illustrating an exemplary impedance characteristic of a resonator when the negative capacitance circuit of the comparative example is connected to the resonator.

FIG. 15 is a graph illustrating an exemplary reflection characteristic when the negative capacitance circuit of the comparative example is observed from the external interface.

FIG. 16 is a circuit diagram illustrating an exemplary configuration of a negative capacitance circuit according to a sixth embodiment.

FIG. 17 is a circuit diagram illustrating an exemplary configuration of a conventional oscillator circuit.

### DETAILED DESCRIPTION

### Configuration of Oscillator 100 of First Embodiment

FIG. 1 illustrates an exemplary configuration of an oscillator 100 according to the first embodiment. The oscillator 100 includes a resonance circuit 1 and an amplifier circuit 2. The amplifier circuit 2 functions as a return unit that returns a signal that is output from a second resonator 12 to a first resonator 11. Since the resonance circuit 1 and the amplifier circuit 2 form a loop, the oscillator 100 can generate an oscillation signal of the resonance frequency of the resonance circuit 1.

### Configuration of Resonance Circuit 1

The resonance circuit 1 includes a first resonator circuit 10, the second resonator 12, and a negative capacitance circuit 15. The first resonator circuit 10 includes the first resonator 11, an inverting amplifier 13, and a capacitance element 14. Examples of the first resonator 11 and second resonator 12 include an AT-cut crystal resonator, an SC-cut crystal resonator, and an MEMS resonator. The first resonator 11 and second resonator 12 are connected each other in series.

In the first embodiment, a resonance frequency fr₁ of the first resonator 11 is about 51.9 MHz, and an anti-resonance frequency fa₁ of the first resonator 11 is about 52.0 MHz. A resonance frequency fr₂ of the second resonator 12 is about 52.1 MHz, and an anti-resonance frequency fa₂ of the second resonator 12 is about 52.2 MHz. Namely, the relation of the resonance frequencies of the first resonator 11 and the second resonator 12, and the anti-resonance frequencies of the first resonator 11 and the second resonator 12 is fr₁<fa₁<fr₂<fa₂.

The inverting amplifier 13 and the capacitance element 14 are connected to each other in series, and are connected to the first resonator 11 in parallel. Namely, the input terminal of the inverting amplifier 13 is connected to one end of the first resonator 11, while the output terminal of the inverting amplifier 13 is connected to one end of the capacitance element 14. The other end of the capacitance element 14 is connected to a node that is disposed between the first resonator 11 and the second resonator 12. The gain of the inverting amplifier 13 is preferably one.

The negative capacitance circuit 15 is disposed between the node that is disposed between the first resonator 11 and the second resonator 12, and ground. The negative capacitance circuit 15 is a circuit that has a property of outputting an electric discharge when a positive voltage is applied. For example, the negative capacitance circuit 15 includes a known circuit formed by incorporating active elements such as an operational amplifier or a plurality of transistors, and passive elements such as a capacitor and a resistor.

FIG. 2 illustrates a simulation circuit using an equivalent circuit of the resonance circuit 1 according to the first embodiment. In FIG. 2, the resonance circuit 1 is connected to an AC signal source 16 and a load resistor 17. The AC signal source 16 and load resistor 17 are disposed for simulating the operation of the resonance circuit 1 when the resonance circuit 1 is used for the oscillator 100 illustrated in FIG. 1.

In the first resonator 11, an equivalent parallel capacitance 111 is connected in parallel to: an equivalent series capacitance 112; an equivalent series inductor 113; and an equivalent series resistor 114, which are connected to one another in series. In the second resonator 12, an equivalent parallel capacitance 121 is connected in parallel to: an equivalent series capacitance 122; an equivalent series inductor 123; and an equivalent series resistor 124, which are connected to one another in series.

The capacitance element 14 has a capacitance equal to the capacitance of the equivalent parallel capacitance 111 of the first resonator 11. The signal output from the AC signal source 16 is input into the equivalent parallel capacitance 111 and is input into the inverting amplifier 13. The signal input into the capacitance element 14 via the inverting amplifier 13 has a reverse phase with respect to a signal input into the equivalent parallel capacitance 111. Accordingly, the signal that has passed through the equivalent parallel capacitance 111 is canceled by the signal that has passed through the capacitance element 14 whose capacitance is equal to the equivalent parallel capacitance 111.

The capacitance value of the negative capacitance circuit 15 has, for example, an opposite sign with respect to the capacitance values of the capacitance element 14, the equivalent parallel capacitance 111, and the equivalent parallel capacitance 121, and is equal to the sum of the capacitance values of the capacitance element 14, the equivalent parallel capacitance 111, and the equivalent parallel capacitance 121. Since the negative capacitance circuit 15 is disposed between the first resonator 11 and the second resonator 12, the influences of the equivalent parallel capacitance 111, the capacitance element 14, and the equivalent parallel capacitance 121 are canceled. Accordingly, the resonance circuit 1 is insusceptible to the anti-resonance frequency of the first resonator 11, and easily oscillates at a frequency between the resonance frequency of the first resonator 11 and the resonance frequency of the second resonator 12. In this way, the capacitance element 14 and the equivalent parallel capacitance 111 of the first resonator circuit 10 and the equivalent parallel capacitance 121 of the second resonator 12 are invisible from the node to which the negative capacitance circuit 15 is connected, or a connecting point of the first resonator circuit 10 and the second resonator 12. Accordingly, a resonance frequency can be established in between the resonance frequency of the first resonator 11 and the resonance frequency of the second resonator 12.

Note that the resonance frequency of the resonance circuit 1 will be close to the resonance frequency of the first resonator 11 if the capacitance value of the negative capacitance circuit 15 becomes smaller than the sum of the capacitance values of the capacitance element 14, the equivalent parallel capacitance 111, and the equivalent parallel capacitance 121. Also, the resonance frequency of the resonance circuit 1 will be close to the resonance frequency of the second resonator 12 if the capacitance value of the negative capacitance circuit 15 becomes larger than the sum of the capacitance values of the capacitance element 14, the equivalent parallel capacitance 111, and the equivalent parallel capacitance 121. Accordingly, the resonance frequency of the resonance circuit 1 can vary by changing the capacitance value of the negative capacitance circuit 15. For example, use of a variable capacitance element such as a varicap diode for the negative capacitance circuit 15 allows to change the resonance frequency of the resonance circuit 1 by changing the voltages applied to that variable capacitance element.

FIG. 3A illustrates an exemplary frequency characteristic of the gain of the resonance circuit 1 according to the first embodiment. The dashed line in FIG. 3A indicates a frequency characteristic of a gain of the first resonator circuit 10. Also the one-dot chain line in FIG. 3A indicates a frequency characteristic of a gain of the second resonator 12. Also, the solid line in FIG. 3A indicates a frequency characteristic of a gain of the resonance circuit 1. FIG. 3B illustrates an exemplary frequency characteristic of a phase of the resonance circuit 1 according to the first embodiment. The dashed line in FIG. 3B indicates a phase of the first resonator circuit 10. Also the one-dot chain line in FIG. 3B indicates a phase of the second resonator 12. The solid line in FIG. 3B indicates a phase of the resonance circuit 1.

As illustrated in FIG. 3A, in the frequency characteristic of the gain of the first resonator circuit 10, the gain has a large peak at near 51.9 MHz, which is the resonance frequency of the first resonator 11. In the frequency characteristic of the gain of the second resonator 12, the gain has a large peak at near 52.1 MHz, which is the resonance frequency of the second resonator 12. Also in the frequency characteristic of the gain of the resonance circuit 1, the gain has a large peak at near 52.0 MHz, which is between the resonance frequency of the first resonator 11 and the resonance frequency of the second resonator 12. Thus, it is found that the resonance circuit 1 has its resonance frequency between the resonance frequency of the first resonator 11 and the resonance frequency of the second resonator 12. Also, as illustrated in FIG. 3B, the phases of the first resonator 11, the second resonator 12, and the resonance circuit 1 are respectively rotated 180 degrees at the frequencies corresponding to the peaks of the gains.

In the frequency characteristics of the gains of the second resonator 12 and the resonance circuit 1, the gains have small peaks at near 52.2 MHz, which is the anti-resonance frequency of the second resonator 12. In contrast, as illustrated by the dashed line in FIG. 3A, in the frequency characteristic of the gain of the first resonator circuit 10, the anti-resonance frequency is not observed. This is because the anti-resonance frequency of the first resonator circuit 10 becomes higher than the resonance frequency fr₂ of the second resonator 12 since the first resonator 11 is connected to the inverting amplifier 13 and capacitance element 14 in parallel due to the following reason.

The anti-resonance frequency fa₁ of the first resonator 11 is expressed by fa₁=fr₁·(½π)√{1+C₁/C₀}. Note that C₀ is a capacitance value of the equivalent parallel capacitance 111 in the first resonator 11, and C₁ is a capacitance value of the equivalent series capacitance 112 in the first resonator 11. As is clear from the above-described expression, as the capacitance value of the equivalent parallel capacitance 111 in the first resonator 11 decreases, the anti-resonance frequency fa₁ tends to increase.

In the first resonator circuit 10 according to the first embodiment, since the inverting amplifier 13 and the capacitance element 14 cancel C₀, the anti-resonance frequency fa₁ of the first resonator circuit 10 becomes larger than the resonance frequency fr₂ of the second resonator 12. Consequently, in the resonance circuit 1, the oscillation condition is satisfied in the whole frequency range between the resonance frequency fr₁ of the first resonator 11 and the resonance frequency fr₂ of the second resonator 12. Accordingly, the resonance circuit 1 can change its resonance frequency in a wide frequency range.

### Comparative Example

FIG. 3C illustrates, as a comparative example, a frequency characteristic of a gain of a circuit formed by removing the inverting amplifier 13, the capacitance element 14, and the negative capacitance circuit 15 from the resonance circuit 1. The dashed line in FIG. 3C indicates a frequency characteristic of a gain of the first resonator 11. Also, the one-dot chain line in FIG. 3C indicates a frequency characteristic of a gain of the second resonator 12. Also, the solid line in FIG. 3C indicates a frequency characteristic of a gain of the circuit of the comparative example to which the first resonator 11 and the second resonator 12 are connected in series.

As illustrated in FIG. 3C, the circuit formed by removing the inverting amplifier 13, the capacitance element 14, and the negative capacitance circuit 15 from the resonance circuit 1, the anti-resonance frequency fa₁ of the first resonator 11 exists between the resonance frequency fr₁ of the first resonator 11 and the resonance frequency fr₂ of the second resonator 12. Accordingly, when the frequency is attempted to vary between the resonance frequency fr₁ of the first resonator 11 and the resonance frequency fr₂ of the second resonator 12, the oscillation condition is not satisfied across the whole frequency range between the resonance frequency fr₁ of the first resonator 11 and the resonance frequency fr₂ of the second resonator 12, but is satisfied only in a narrow frequency range.

### Effect of First Embodiment

As described above, the resonance circuit 1 according to the first embodiment includes the first resonator 11, the second resonator 12, the inverting amplifier 13, the capacitance element 14, and the negative capacitance circuit 15. The second resonator 12 is connected to the resonance circuit 1 in series. The inverting amplifier 13 and the capacitance element 14 are connected to the first resonator 11 in parallel, and are connected each other in series. The negative capacitance circuit 15 is disposed between the node between the first resonator 11 and the second resonator 12, and ground. Accordingly, a resonance frequency can be set between the resonance frequency fr₁ of the first resonator 11 and the resonance frequency fr₂ of the second resonator 12.

### Connecting Variable Resistors to Resonators in Parallel of Second Embodiment

FIG. 4 illustrates an exemplary configuration of a resonance circuit 1 according to a second embodiment. The resonance circuit 1 illustrated in FIG. 4 further includes a first variable resistor 18 and a second variable resistor 19. Only at this point, the resonance circuit 1 illustrated in FIG. 4 is different from the resonance circuit 1 illustrated in FIG. 2, otherwise they are same.

The first variable resistor 18 is connected to the first resonator 11 in parallel. The second variable resistor 19 is connected to the second resonator 12 in parallel. A current passing through the first resonator 11 is adjusted by adjusting a resistance value of the first variable resistor 18. Also, a current passing through the second resonator 12 is adjusted by adjusting a resistance value of the second variable resistor 19.

For example, when a resistance value of the first variable resistor 18 is relatively large with respect to a resistance value of the equivalent series resistor 114, and a resistance value of the second variable resistor 19 is relatively small with respect to a resistance value of the equivalent series resistor 124, a current output from the AC signal source 16 passes through the first resonator circuit 10. Then, the relatively big proportion of the current passing through the first resonator circuit 10 passes through the second variable resistor 19. Accordingly, in this case, the resonance circuit 1 is hardly influenced by the second resonator 12, and among signals passed through the first resonator circuit 10, the signals having frequencies far from the resonance frequency of the second resonator 12 are not attenuated too. Accordingly, the resonance frequency of the resonance circuit 1 becomes closer to the resonance frequency of the first resonator circuit 10 compared with the resonance frequency of the second resonator 12.

On the other hand, when the resistance value of the first variable resistor 18 is relatively small with respect to the equivalent series resistor 114, and the resistance value of the second variable resistor 19 is relatively large with respect to the equivalent series resistor 124, a current output from the AC signal source 16 passes through the first variable resistor 18 with being hardly influenced by the first resonator circuit 10. Then, the relatively big proportion of the currents passing through the first variable resistor 18 passes through the second resonator 12. Accordingly, in this case, the resonance circuit 1 is hardly influenced by the first resonator circuit 10, and the signals having frequencies far from the resonance frequency of the first resonator circuit 10 are input into the second resonator 12 without being attenuated. Accordingly, the resonance frequency of the resonance circuit 1 moves closer to the resonance frequency of the second resonator 12 compared with the resonance frequency of the first resonator circuit 10.

Changing the resistance values of the first variable resistor 18 and the second variable resistor 19 changes the attenuation amount of each frequency component of the signal input into the resonance circuit 1 when passing through the first resonator circuit 10 and the second resonator 12. Then, the resonance circuit 1 resonates at the frequency whose attenuated amount is the smallest while the signal passes through the first resonator circuit 10 and second resonator 12.

### Effect of Second Embodiment

As described above, the resonance circuit 1 according to the second embodiment further includes the first variable resistor 18 and second variable resistor 19. Accordingly, the resonance circuit 1 can adjust the resonance frequency of the resonance circuit 1 between the resonance frequency of the first resonator 11 and the resonance frequency of the second resonator 12. Namely, the resonance circuit 1 according to the second embodiment can change the peak frequency in the frequency characteristic of the resonance circuit 1 illustrated by the solid line in FIG. 3A between the resonance frequency fr₁ of the first resonator 11 and the resonance frequency fr₂ of the second resonator 12 in response to the resistance values of the first variable resistor 18 and second variable resistor 19.

### Third embodiment

### Variable Capacitance Element Between the First Resonator 11 and the Second Resonator 12

FIG. 5 illustrates an exemplary configuration of the resonance circuit 1 according to a third embodiment. The resonance circuit 1 according to the third embodiment is different from the resonance circuit 1 illustrated in FIG. 4 in that the resonance circuit 1 according to the third embodiment further includes a variable capacitance element 20. The resonance circuit 1 according to the third embodiment is otherwise same as the resonance circuit 1 illustrated in FIG. 4. FIG. 6A illustrates an exemplary frequency characteristic of a gain of the resonance circuit 1 according to the third embodiment. FIG. 6B illustrates an exemplary frequency characteristic of a phase of the resonance circuit 1 according to the third embodiment.

The variable capacitance element 20 is disposed between the first resonator 11 and the second resonator 12. The variable capacitance element 20 is, for example, an element group including a varicap diode or a series connection of a field effect transistor (FET) and a resistor. The capacitance value of the variable capacitance element 20 can vary by changing the resonance frequency of the resonance circuit 1.

The dashed line in FIG. 6A indicates a frequency characteristic of a gain of the resonance circuit 1 in which the second variable resistor 19 is short-circuited with the capacitance value of the variable capacitance element 20 being sufficiently large. In this state, since the frequency characteristic of the first resonator 11 strongly influences the frequency characteristic of the resonance circuit 1, the resonance frequency of the resonance circuit 1 is close to the resonance frequency of the first resonator 11. The resonance frequency of the resonance circuit 1 increases and moves to a frequency characteristic indicated by the solid line by decreasing the capacitance value of the variable capacitance element 20 with the second variable resistor 19 short-circuited.

Also, when the resistance value of the second variable resistor 19 and the capacitance value of the variable capacitance element 20 sufficiently increase to make the resonance frequency of the resonance circuit 1 to become a frequency at near the middle of the resonance frequency of the first resonator 11 and the resonance frequency of the second resonator 12. Then, the capacitance value of the variable capacitance element 20 decreases. This allows the frequency characteristic of the second resonator 12 to strongly influence the frequency characteristic of the resonance circuit 1. Consequently, as indicated by the one-dot chain line in FIG. 6A, the frequency characteristic of the resonance circuit 1 comes close to a frequency characteristic of the second resonator 12.

### Effect of Third Embodiment

As described above, the resonance circuit 1 according to the third embodiment further includes the variable capacitance element 20. Accordingly, the resonance frequency of the resonance circuit 1 can vary more freely.

### Fourth Embodiment

FIG. 7 illustrates an exemplary configuration of an oscillator 200 according to a fourth embodiment. The resonance circuit 1 of the oscillator 200 illustrated in FIG. 7 is different from the resonance circuit 1 of the oscillator 100 illustrated in FIG. 1 in that the resonance circuit 1 of the oscillator 200 further includes: a third resonator 21; a negative capacitance circuit 22; an inverting amplifier 23; and a capacitance element 24. The resonance circuit 1 of the oscillator 200 is otherwise same as the resonance circuit 1 of the oscillator 100.

The resonance frequency of the third resonator 21 is higher than the resonance frequency of the second resonator 12. The capacitance value of the negative capacitance circuit 22 has an opposite sign of the inter-terminal capacitance of the second resonator 12 and the inter-terminal capacitance of the third resonator 21, and the capacitance element 24, and is equal to the sum of these capacitance values. The inverting amplifier 23 and capacitance element 24 cancel the inter-terminal capacitance of the second resonator 12.

The resonance circuit 1 illustrated in FIG. 7 includes the negative capacitance circuit 22, the inverting amplifier 23, and the capacitance element 24. Thus, the anti-resonance frequency of the first resonator 11 and the anti-resonance frequency of the second resonator 12 are higher than the resonance frequency of the third resonator 21. Accordingly, the oscillator 200 oscillates at a frequency between the resonance frequency of the first resonator 11 and the resonance frequency of the third resonator 21. Changing the capacitance value of the negative capacitance circuit 22 allow changing the oscillation frequency of the oscillator 200 between the resonance frequency of the first resonator 11 and the resonance frequency of the third resonator 21. Note that similarly to the second embodiment, a variable resistor can be connected to the third resonator 21 in parallel to change the resistance value of the variable resistor, as well as, similarly to the third embodiment, a variable capacitance element can be connected between the second resonator 12 and the third resonator 21 to change the capacitance value of the variable capacitance element. This can change the oscillation frequency of the oscillator 200.

### Effect of the Fourth Embodiment

As described above, the oscillator 200 according to the fourth embodiment further includes the third resonator 21, the negative capacitance circuit 22, the inverting amplifier 23, and the capacitance element 24. Accordingly, the oscillator 200 can change its oscillation frequency in a frequency range wider than a range of the embodiments described above.

Above all, although the present disclosure has been described with reference to the embodiments, the technical scope of the present disclosure is not limited to the scope of the embodiments. It is apparent that a variety of the variations and modifications of the above-described embodiments can be made by those skilled in the art. It is apparent that such variations and modifications of the embodiments can be encompassed in the technical scope of the disclosure.

For example, while in the first embodiment the inverting amplifier 13 and the capacitance element 14 are connected to the first resonator 11 in parallel, a circuit equivalent to the inverting amplifier 13 and the capacitance element 14 can be connected to the second resonator 12 in series. While in the fourth embodiment the oscillator 200 including three resonators has been described, the oscillator 200 may include more resonators.

In the resonance circuit, the capacitance element may have, for example, an equivalent parallel capacitance of the first resonator. The negative capacitance circuit may have a variable capacitance value.

The above-described resonance circuit may further include a first variable resistor connected to the first resonator in parallel and a second variable resistor connected to the second resonator in parallel. The above-described resonance circuit may include a variable capacitance element connected to between the first resonator and the second resonator.

The second embodiment provides an oscillator circuit that includes: a first resonator; a second resonator connected to the first resonator in series; a capacitance element and an inverting amplifier connected to one another in series and connected to the first resonator in parallel; a negative capacitance circuit connected between a node disposed between the first resonator and the second resonator and ground; and a return unit configured to return a signal output from the second resonator to the first resonator.

The oscillator circuit according to the disclosure can be incorporated into an integrated circuit, and can resonate at a frequency different from the resonance frequency of resonators.

### Circuit Configuration of Oscillator Circuit 100a of Fifth Embodiment

FIG. 8A illustrates an exemplary configuration of an oscillator circuit 100a according to a fifth embodiment. The oscillator circuit 100a includes a negative capacitance circuit 10a, a resonator 6a connected to an external interface 5a of the negative capacitance circuit 10a, and an amplifier circuit 7a. The negative capacitance circuit 10a cancels the equivalent parallel capacitance of the resonator 6a. The negative capacitance circuit 10a includes an emitter follower circuit 1a, a grounded base circuit 2a, a first capacitor 3a, a resistor 4a, and the external interface 5a.

The emitter follower circuit 1a includes a transistor 11a and a resistor 12a. The transistor 11a is, for example, an NPN transistor. The collector of the transistor 11a is connected to a power source. The emitter of the transistor 11a is connected to ground via the resistor 12a. With the above-described configuration, the transistor 11a and resistor 12a form a grounded collector circuit. The emitter of the transistor 11a is connected to the first terminal of the first capacitor 3a, and the base of the transistor 11a is connected to the first terminal of the resistor 4a.

The grounded base circuit 2a includes a transistor 21a, a voltage source 22a, a current source 23a, and a resistor 24a. The transistor 21a is, for example, an NPN transistor. The collector of the transistor 21a is connected to the current source 23a. Also, the collector of the transistor 21a is connected to the second terminal of the resistor 4a, and is connected to the external interface 5a. The emitter of the transistor 21a is connected to ground via the resistor 24a, and is connected to the second terminal of the first capacitor 3a. The base of the transistor 21a is connected to the positive electrode terminal of the voltage source 22a.

The voltage source 22a is a voltage source that provides a base potential to the transistor 21a. The positive electrode terminal of the voltage source 22a is connected to the base of the transistor 21a, and the negative electrode terminal of the voltage source 22a is connected to ground. The voltage value output from the voltage source 22a is set to a value with which the grounded base circuit 2a performs linear operation.

The current source 23a includes, for example, a plurality of the transistors that are cascade connected. While the current source 23a also may include a resistor connected to a power source, the current source 23a preferably includes active elements such as transistors in order to decrease the voltage drop across the current source 23a.

The first capacitor 3a is disposed between the emitter of the transistor 11a as the output terminal of the emitter follower circuit 1a and the emitter of the transistor 21a as the input terminal of the grounded base circuit 2a. The first capacitor 3a inputs a part of the current output from the emitter of the transistor 11a to the emitter of the transistor 21a. The capacitance of the first capacitor 3a is equal to, for example, the equivalent parallel capacitance of the resonator 6a.

The resistor 4a is an attenuator disposed between the base of the transistor 11a as the input terminal of the emitter follower circuit 1a and the collector of the transistor 21a as the output terminal of the grounded base circuit 2a. The resistor 4a has a resistance value, for example, equal to or more than 10Ω, which does not satisfy the amplitude condition of the Colpitts LC oscillator circuit formed by a parasitic capacitor and a parasitic inductor near the emitter follower circuit 1a. Thus, the resistor 4a prevents the undesired oscillation of the emitter follower circuit 1a. Note that the resistor 4a may be resistor network in which a plurality of resistors are combined.

The adjustment of the resistance value of the resistor 4a allows adjusting the frequency at which the equivalent parallel resistance is the largest when the negative capacitance circuit 10a is observed from the external interface 5a. Specifically, the frequency at which the equivalent parallel resistance is the largest can be decreased by increasing the resistance value of the resistor 4a. Therefore, use of, for example, a digital potentiometer, as the resistor 4a, that can adjust a resistance value corresponding to a control signal received from outside can adjust the equivalent parallel resistance of the negative capacitance circuit 10a at the resonance frequency of the resonator 6a to an ideal infinite value.

The resistor 4a is, for example, larger than the negative resistance value that causes an undesired oscillation of the emitter follower circuit 1a. The resistor 4a may be smaller than the resistance value at which the equivalent parallel resistance is the largest at the resonance frequency of the resonator 6a. In the case where the equivalent parallel resistance of the negative capacitance circuit 10a at the resonance frequency of the resonator 6a is close to an infinite value, it is preferred that the negative capacitance circuit 10a only cancels the equivalent parallel capacitance of the resonator 6a and does not affect other characteristics of the oscillator circuit having the resonator 6a and the amplifier circuit 7a.

The external interface 5a is a connecting point of the negative capacitance circuit 10a, the resonator 6a, and the amplifier circuit 7a. The external interface 5a is, for example, a conductive terminal that is connected to the resonator 6a and the amplifier circuit 7a. Note that while the negative capacitance circuit 10a illustrated in FIG. 8A is connected to the resonator 6a and the amplifier circuit 7a, the external interface 5a may be connected to other circuits. Also, the wiring that connects the collector of the transistor 21a and the resonator 6a and amplifier circuit 7a may function as the external interface 5a.

The resonator 6a is connected to the negative capacitance circuit 10a and receives currents output from the collector of the transistor 21a as the output terminal of grounded base circuit 2a. The examples of the resonator 6a include an AT-cut crystal resonator, an SC cut crystal resonator, and an MEMS resonator. The amplifier circuit 7a is an amplifier circuit that causes the resonator 6a to oscillate. The resonator 6a and amplifier circuit 7a form, for example, the Colpitts oscillator circuit, or the Hartley oscillator circuit.

### Principle Causing Negative Capacitance Circuit 10a to Generate Negative Capacitance

The following, qualitatively, describes the principle that causes the negative capacitance circuit 10a to generate a negative capacitance. When a positive AC voltage V is applied to the external interface 5a, the approximately same AC voltage V is applied to the base of the transistor 11a via the resistor 4a. The AC voltage V is directly output to the emitter of the transistor 11a since the transistor 11a operates as an emitter follower. On the other hand, since the impedance of the emitter of the grounded base circuit 2a can be regarded as an approximately zero, the current, which is determined by the capacitance value of the first capacitor 3a and the AC voltage V, flows through the first capacitor 3a.

When the current is input to the emitter of the transistor 21a, the current having approximately the same magnitude is output from the collector of the transistor 21a. Namely, since applying the positive AC voltage V to the external interface 5a allows the current to flow toward the external interface 5a, the negative capacitance circuit 10a operates as if the AC voltage V were applied to the capacitor having a negative capacitance.

In the case where the negative capacitance circuit 10a is connected to the resonator 6a, the equivalent parallel capacitance of the resonator 6a is canceled by the current output from the collector of the transistor 21a. Consequently, the oscillator circuit 100a can oscillate in a state that is equivalent to the state without the equivalent parallel capacitance of the resonator 6a.

The principle that causes the negative capacitance by the negative capacitance circuit 10a can also be described as follows based on an equivalent circuit of the negative capacitance circuit 10a illustrated in FIG. 8B. Assuming that a transconductance of the transistor is gₘ and a current i flows through the external interface 5a when a positive AC voltage v is applied to the external interface 5a, the impedance observed from the external interface 5a is expressed as follows.

Zᵢₙ=v/i=−2/gₘ−1/jωC

Thus, it is similarly found that a negative capacitance with an opposite sign with respect to a capacitance C is generated.

### Simulation Result of Characteristic of Negative Capacitance Circuit 10a

FIG. 9 illustrates an exemplary frequency characteristic of an equivalent RC parallel circuit when the negative capacitance circuit 10a with the resistor 4a adjusted to 1 kΩ, is observed from the external interface 5a. The negative capacitance circuit 10a whose frequency characteristic is illustrated in FIG. 9 can cancel the equivalent parallel capacitance of 1.5 pF of the resonator 6a whose resonance frequency is 10 MHz. The solid line indicates the equivalent parallel resistance of the negative capacitance circuit 10a, and the dotted line indicates the equivalent parallel capacitance of the negative capacitance circuit 10a.

As indicated by the dotted line in FIG. 9, the equivalent parallel capacitance value of the negative capacitance circuit 10a at the frequency of 10 MHz is approximately −1.5 pF. Therefore, the equivalent parallel capacitance of the resonator 6a can be canceled by connecting the negative capacitance circuit 10a to the resonator 6a whose equivalent parallel capacitance value is 1.5 pF.

Also, as indicated by the solid line in FIG. 9, the magnitude of the equivalent parallel resistance at the frequency of 10 MHz, which is the resonance frequency of the resonator 6a, is the positive value larger than 100 kΩ. Accordingly, since the negative capacitance circuit 10a has the characteristic illustrated in FIG. 9, the negative capacitance circuit 10a only cancels the equivalent parallel capacitance of the resonator 6a and does not affect other characteristics of the oscillator circuit including the resonator 6a and the amplifier circuit 7a.

FIG. 10 illustrates an exemplary impedance characteristic of the resonator 6a. The dotted line indicates the impedance characteristic of the independent resonator 6a whose resonance frequency is 10 MHz. The solid line indicates the impedance characteristic of the resonator 6a that is connected to the negative capacitance circuit 10a having the characteristic illustrated in FIG. 10.

As indicated by the dotted line, under the impedance characteristic of the independent resonator 6a, the impedance becomes the local minimum at the resonance frequency due to the influence of the equivalent parallel capacitance of the resonator 6a, and the impedance becomes the local maximum at the anti-resonant frequency that is higher than the resonance frequency. The variable range of the oscillation frequency of the resonator 6a is limited to the frequencies between the resonance frequency and the anti-resonant frequency.

In contrast, as indicated by the solid line, in the case where the resonator 6a is connected to the negative capacitance circuit 10a, the anti-resonant frequency does not present because the equivalent parallel capacitance of the resonator 6a is canceled. Accordingly, compared with the case where the independent resonator 6a oscillates, the frequency can be varied within the wide frequency range without being limited to the frequencies between the resonance frequency and the anti-resonant frequency.

FIG. 11 illustrates an exemplary reflection characteristic when the negative capacitance circuit 10a is observed from the external interface 5a. The horizontal axis indicates the frequency, and the vertical axis indicates the return gain. As illustrated in FIG. 11, the negative resistance is hardly generated even at the frequency exceeding 10 MHz. Consequently, in the case where the negative capacitance circuit 10a is connected to the resonator 6a and the amplifier circuit 7a, an undesired oscillation is not easily caused.

### Comparative Example

FIG. 12 illustrates, as a comparative example, an exemplary configuration of an oscillator circuit 200a in which a negative capacitance circuit 20a is connected to the resonator 6a and the amplifier circuit 7a. The negative capacitance circuit 20a is formed by removing the resistor 4a from the negative capacitance circuit 10a illustrated in FIG. 8A.

FIG. 13 illustrates an exemplary frequency characteristic of the equivalent RC parallel circuit when the negative capacitance circuit 20a is observed from the external interface 5a. The solid line indicates the equivalent parallel resistance, and the dotted line indicates the equivalent parallel capacitance. In FIG. 13, although the equivalent parallel capacitance of the negative capacitance circuit is −1.5 pF at 10 MHz, which is the resonance frequency of the resonator 6a, the equivalent parallel resistance is only 20 kΩ that is not preferable.

FIG. 14 illustrates an exemplary impedance characteristic of the resonator 6a when the negative capacitance circuit 20a is connected to the resonator 6a. In FIG. 14, the solid line indicates the impedance characteristic of the resonator 6a connected to the negative capacitance circuit 10a (illustrated in FIG. 10), and the dotted line indicates the impedance characteristic of the resonator 6a connected to the negative capacitance circuit 20a. At frequencies other than the resonance frequency, the impedance of the resonator 6a connected to the negative capacitance circuit 20a is lower than the impedance of the resonator 6a connected to the negative capacitance circuit 10a. Since high impedance is preferred at the frequencies other than the resonance frequency, the negative capacitance circuit 10a having the resistor 4a is more preferable.

FIG. 15 illustrates an exemplary reflection characteristic when the negative capacitance circuit 20a is observed from the external interface 5a. The horizontal axis indicates the frequency, and the vertical axis indicates the return gain. In FIG. 15, the dotted line indicates a reflection characteristic when the resonator 6a is connected to the negative capacitance circuit 10a (illustrated in FIG. 11), and the solid line indicates a reflection characteristic when the resonator 6a is connected to the negative capacitance circuit 20a. As apparent from FIG. 15, in the case where the negative capacitance circuit 20a is connected to the resonator 6a, the return gain increases rapidly at the frequencies larger than 100 MHz. Accordingly, an undesired oscillation is likely to occur at the frequencies in which the return gain is large.

### Effect of Fifth Embodiment

As described above, the negative capacitance circuit 10a according to the fifth embodiment includes the emitter follower circuit 1a, the grounded base circuit 2a, the first capacitor 3a disposed between the output terminal of the emitter follower circuit 1a and the input terminal of the grounded base circuit 2a, and the resistor 4a disposed between the output terminal of the grounded base circuit 2a and the input terminal of the emitter follower circuit 1a. Thus, the negative capacitance circuit 10a can successfully cancel the equivalent parallel capacitance of the connected resonator 6a, and prevents an undesired oscillation.

### Sixth Embodiment

FIG. 16 illustrates an exemplary configuration of the negative capacitance circuit 10a according to the sixth embodiment. The negative capacitance circuit 10a illustrated in FIG. 16 is different from the negative capacitance circuit 10a illustrated in FIG. 8A in that the negative capacitance circuit 10a illustrated in FIG. 16 includes a resistor 8a disposed between the collector of the transistor 21a as the output terminal of the grounded base circuit 2a and the external interface 5a, and a second capacitor 9a connected to the resistor 8a in parallel. The negative capacitance circuit 10a illustrated in FIG. 16 is otherwise same as the negative capacitance circuit 10a illustrated in FIG. 8A.

The resistor 8a has the resistance value of the order of several hundreds Ω, and the second capacitor 9a has the capacitance value of the order of several pF to several tens pF. The negative capacitance circuit 10a includes the resistor 8a and the second capacitor 9a. Thus, the negative resistance of the negative capacitance circuit 10a decreases at higher frequencies than the resonance frequency of the resonator 6a connected to the negative capacitance circuit 10a. This can effectively prevent an undesired oscillation at the higher frequencies than the resonance frequency of the resonator 6a.

### Other Variations

In the above-described embodiments, the emitter follower circuit 1a and the grounded base circuit 2a include bipolar transistors. However, the emitter follower circuit 1a may include a field effect transistor to work as a source follower circuit, and the grounded base circuit 2a may include a field effect transistor to work as a grounded gate circuit.

In the case where the emitter follower circuit 1a and the grounded base circuit 2a include a field effect transistor, the collector of the bipolar transistor in the above-described embodiment is substituted by the drain of the field effect transistor, and the emitter of the bipolar transistor is substituted by the source of the field effect transistor, and the base of the bipolar transistor is substituted by the gate of the field effect transistor.

While in the present disclosure has been described above with reference to the embodiments, the technical scope of the disclosure is not limited to the scope of the embodiments described above. It is apparent that a variety of variations and modifications of the above-described embodiments can be made by those skilled in the art. For example, while in the above-described embodiments an example includes the grounded base circuit 2a having one transistor, the grounded base circuit 2a may include more than one transistors. It is apparent from accompanying claims that such variations and modifications may also encompassed by the technical scope of the disclosure.

A first aspect of the disclosure provides a negative capacitance circuit that includes: an emitter follower circuit; a grounded base circuit connected to a load with a capacitance component; a first capacitor disposed between the output terminal of the emitter follower circuit and the input terminal of the grounded base circuit; and an attenuator disposed between the output terminal of the grounded base circuit and the input terminal of the emitter follower circuit. The above-described negative capacitance circuit may further include: a resistor disposed between the output terminal of the grounded base circuit and the external interface to be connected to an external circuit; and a second capacitor connected to the resistor in parallel.

A second aspect of the disclosure provides an oscillator circuit that includes: a negative capacitance circuit having an emitter follower circuit, a grounded base circuit, a capacitor disposed between the output terminal of the emitter follower circuit and the input terminal of the grounded base circuit, an attenuator disposed between the input terminal of the emitter follower circuit and the output terminal of the grounded base circuit; and a resonator that is connected to the negative capacitance circuit and resonator receives a current output from the output terminal of the grounded base circuit.

The resistance value of the equivalent parallel resistance of the above described negative capacitance circuit preferably takes a positive value at the resonance frequency of the above described resonator. The capacitance of the above described capacitor is equal to, for example, the equivalent parallel capacitance of the above described resonator.

In addition, the resistance value of the above described attenuator is preferably larger than the negative resistance value that causes the undesired oscillation of the emitter follower circuit, and smaller than the resistance value at which the equivalent parallel resistance of the negative capacitance circuit is the largest at the resonance frequency of the resonator. In addition, the above described negative capacitance circuit may further include: a resistor disposed between the output terminal of the grounded base circuit and the above described resonator; and a capacitor connected to the resistor in parallel.

The oscillator circuit according to this disclosure can be incorporated into the integrated circuit, and can generate the oscillation signals having the variable oscillation frequencies within the wide frequency range.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A resonance circuit, comprising:
a first resonator;
a second resonator, being connected to the first resonator in series;
a capacitance element and an inverting amplifier, being connected to one another in series, the capacitance element and the inverting amplifier being connected to the first resonator in parallel; and
a negative capacitance circuit, being connected between a node and ground, and the node being disposed between the first resonator and the second resonator.

2. The resonance circuit according to claim 1, wherein
the capacitance element has an equivalent parallel capacitance of the first resonator.

3. The resonance circuit according to claim 1, wherein
the negative capacitance circuit has a variable capacitance value.

4. The resonance circuit according to claim 1, further comprising:
a first variable resistor, being connected to the first resonator in parallel; and
a second variable resistor, being connected to the second resonator in parallel.

5. The resonance circuit according to claim 1, further comprising:
a variable capacitance element, being connected to between the first resonator and the second resonator.

6. An oscillator circuit, comprising:
the resonance circuit according to claim 1; and
a return unit, being configured to return a signal output from the second resonator to the first resonator.

7. The resonance circuit according to claim 1, wherein
the negative capacitance circuit include:
an emitter follower circuit;
a grounded base circuit, being connected to a load with a capacitance component;
a first capacitor, being connected to between an output terminal of the emitter follower circuit and an input terminal of the grounded base circuit; and
an attenuator, being connected to between an output terminal of the grounded base circuit and an input terminal of the emitter follower circuit.

8. The resonance circuit according to claim 7, wherein
the negative capacitance circuit further include:
a resistor, being connected to between an output terminal of the grounded base circuit and an external interface to be connected to an external circuit;
a second capacitor, being connected to the resistor in parallel.

9. A negative capacitance circuit for use in a resonance circuit, comprising:
an emitter follower circuit;
a grounded base circuit, being connected to a load with a capacitance component;
a first capacitor, being connected to between an output terminal of the emitter follower circuit and an input terminal of the grounded base circuit; and
an attenuator, being connected to between an output terminal of the grounded base circuit and an input terminal of the emitter follower circuit.

10. The negative capacitance circuit according to claim 9, further comprising:
a resistor, being connected to between an output terminal of the grounded base circuit and an external interface to be connected to an external circuit; and
a second capacitor, being connected to the resistor in parallel.

11. An oscillator circuit, comprising:
the negative capacitance circuit according to claim 9;
a resonator, being connected to the negative capacitance circuit for receiving a current output from the output terminal of the grounded base circuit.

12. The oscillator circuit according to claim 11, wherein
the negative capacitance circuit has an equivalent parallel resistance with a positive resistance value at a resonant frequency of the resonator.

13. The oscillator circuit according to claim 11, wherein
the capacitor has a same capacitance as an equivalent parallel capacitance of the resonator.

14. The oscillator circuit according to claim 11, wherein
the attenuator has a resistance value that is larger than a negative resistance value that causes an undesired oscillation of the emitter follower circuit, and is smaller than a resistance value at which the equivalent parallel resistance of the negative capacitance circuit is largest at a resonance frequency of the resonator.

15. The oscillator circuit according to claim 11, further comprising:
a resistor, being connected to between the output terminal of the grounded base circuit and the resonator; and
a capacitor, being connected to the resistor in parallel.
